(19) United States
(12) Patent Application Publication
(10) Pub. No.: US 2008/0294452 A1
(43) Pub. Date: Nov. 27, 2008

(54) Managing Supply of a Utility to a Customer Premises

(76) Inventor: Stephen Gregory Hunt, Darfield (NZ)

Correspondence Address: TOWNSEND AND TOWNSEND AND CREW, LLP, TWO EMBARCADERO CENTER, EIGHTH FLOOR, SAN FRANCISCO, CA, 94111-3834, US

(21) Appl. No.: 12/095,112

(22) PCT Filed: Aug. 31, 2007
(86) PCT No.: PCT/NZ07/00242

§ 371 Date: Jul. 18, 2008

(30) Foreign Application Priority Data
Aug. 31, 2006 (NZ) 549548

(51) Int. Cl. G06Q 10/00; G01R 11/00

(52) U.S. Cl. 705/1; 705/412

(57) ABSTRACT

The invention provides a method of managing supply of a utility to a customer premises. A utility meter and a disconnect switch are installed at the customer premises. A management system remote from the customer premises is interfaced to the utility meter and disconnect switch over a data network. The method includes transmitting a termination instruction over the data network if the utility meter has not received configuration information from the management system; transmitting an initiation instruction over the data network if the utility meter has received an override switch ON command from the management system; transmitting a termination instruction over the data network on detecting tampering with the meter; and transmitting a termination instruction over the data network causing activation of the disconnect switch to terminate supply of the utility if the utility meter has received an override switch OFF command from the management system.

### FIELD OF INVENTION

The invention relates to a method of managing supply of a utility to a customer premises. More particularly but not exclusively it relates to rules for managing supply of electricity.

### BACKGROUND TO THE INVENTION

Recent advances in metering technology permit the supply of electricity to a customer premises to be initiated or terminated remotely.

It is an object of the present invention to provide an improved or alternative method for managing supply of a utility to a customer premises, or to at least provide the public with a useful choice.

### SUMMARY OF THE INVENTION

In broad terms in one form the invention provides a method of managing supply of a utility to a customer premises. A utility meter and a disconnect switch are installed at the customer premises. A management system remote from the customer premises is interfaced to the utility meter and disconnect switch over a data network. The method includes transmitting a termination instruction over the data network causing activation of the disconnect switch to terminate supply of the utility if the utility meter has not received configuration information from the management system; transmitting a termination instruction over the data network causing activation of the disconnect switch to initiate supply of the utility if the utility meter has received an override switch ON command from the management system; transmitting a termination instruction over the data network causing activation of the disconnect switch to terminate supply of the utility on detecting tampering with the meter; and transmitting a termination instruction over the data network causing activation of the disconnect switch to terminate supply of the utility if the utility meter has received an override switch OFF command from the management system. Other aspects of the invention may become apparent from the following description which is given by way of example only and with reference to the accompanying figures.

The term “comprising” as used in this specification and claims means “consisting at least in part of”; that is to say when interpreting statements in this specification and claims which include “comprising”, features, other than those prefaced by this term in each statement, can also be present. Related terms such as “comprise” and “comprised” are to be interpreted in similar manner.

To those skilled in the art to which the invention relates, many changes in the construction and widely differing embodiments and applications of the invention will suggest themselves without departing from the scope of the invention as defined in the appended claims. The disclosures and the descriptions herein are purely illustrative and are not intended to be in any sense limiting.

### BRIEF DESCRIPTION OF THE FIGURES

Preferred forms of the method of managing supply of a utility will be described by way of example only and with reference to the accompanying figures in which:

FIG. 1 shows a block diagram of a system in which one form of the invention may be implemented;

FIGS. 2 to 5 show preferred form message formats;

FIG. 6 shows a flow chart of a preferred form method of the invention operating in post-payment mode; and

FIGS. 7A and 7B show a flow chart of a preferred form method of the invention operating in prepayment mode.

### DETAILED DESCRIPTION OF PREFERRED FORMS

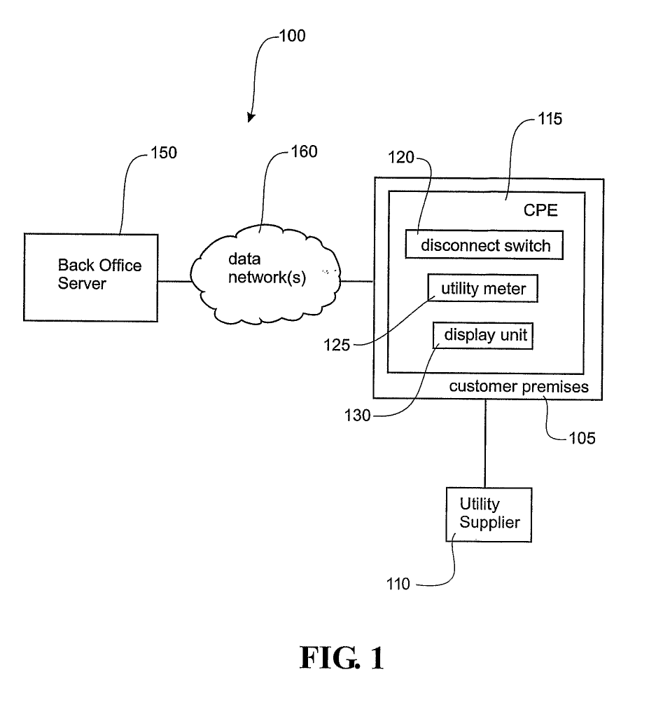

FIG. 1 illustrates a block diagram of the preferred system 100 in which one form of the present invention may be implemented. The system includes a customer premises designated generally at 105. The customer premises 105 receives supply of a utility from a utility supplier 110. The utility described below is electricity. It will be appreciated that other utilities include for example gas and water. Also included is domestic equipment control techniques. Examples of domestic equipment include refrigerators, air conditioners and alarms.

Customer premises equipment (CPE) 115 is positioned at the customer premises 105. The CPE 115 includes a mains disconnect switch 120. The disconnect switch 120 enables the utility to be switched on or off at customer premises 105. Also included in CPE 115 is a utility meter 125. The CPE 115 could further include a display unit 130 configured to display information to a customer at the customer premises 105.

The system 100 further includes a data collection display management and control system. This system is referred to generally as a management system or back office system or server 150. Back office system 150 includes communication and networking hardware as well as proprietary software.

Back office server 150 is interfaced to CPE 115 in a manner that enables remote readings of utility usage at the customer premises 105. Back office server 150 is able to read utility meter 125. Back office server 150 is also configured to operate disconnect switch 120 to initiate or terminate supply of the utility to the customer premises 105. Back office server 150 transmits initiate or terminate instructions over data network(s) 160 causing activation of the disconnect switch to either initiate or terminate supply of the utility.

Back office server is configured to operate disconnect switch 120 in one of four modes. These modes include automatic mode, forced on mode, forced off mode and armed. These modes are described further below.

System 100 supports two way message transfer between one or more CPE 115 and the back office server 150 over one or more data networks 160. In one embodiment SMS is used to transport messages over a GSM network. In other embodiments a TCP/IP stack is used over a GPRS link.

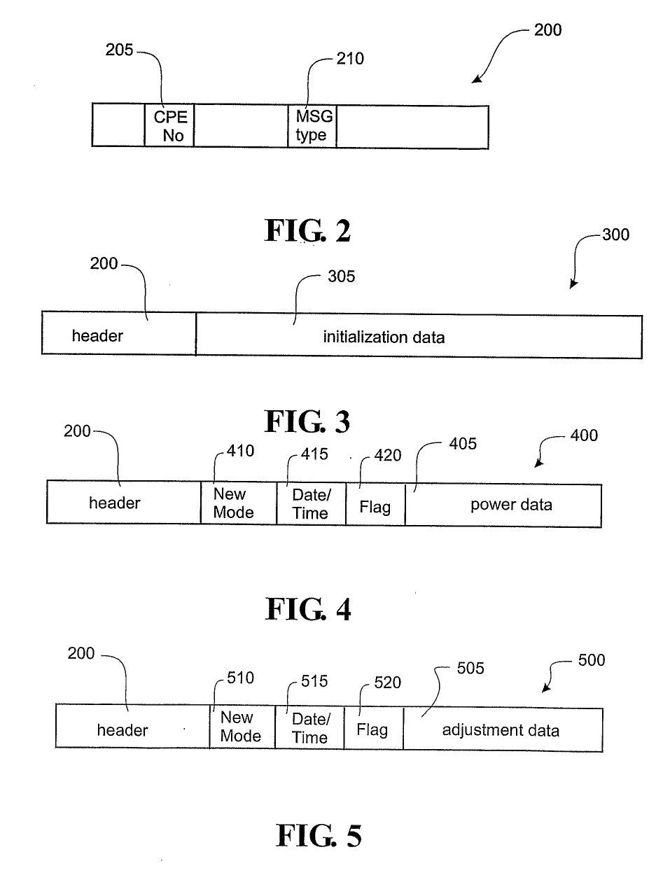

Messages transmitted from back office server 150 to CPE 115 typically have a common fixed length header. A typical header 200 is shown in FIG. 2.

The common header 200 includes a CPE number 205. This is a unique identification number for identifying the CPE 115 to which the message is addressed.

Each header also includes a message type 210. All non global message types have a message type identified by a number in a first range of numbers All global message types are identified by a number in a second range of numbers.

Any messages addressed to an individual CPE 115 will have a non zero CPE identifier specified. If the message is sent as a group addressed message, the CPE ID is a non zero group ID. If the message is sent as a global addressed message, it has an all zero group ID or correct group ID for this individual.

One of the possible message types 210 in the header is an initialisation message. An initialisation message contains a unique identifier for the CPE 115. It also contains data relating to the number of meters connected at the CPE and how they should be configured, tamper detection configuration data, extended service configuration data, configuration data relating to the connected display, initial meter register/money balance values and so on.

Further configuration messages can be sent in the same format as the initialisation message. Configuration messages allow selective reconfiguration of any of the parameters passed in the initialisation message.

When the CPE is configured for the first time, back office server sends at least an initialisation message, a power message, and a global adjustment message to the CPE.

FIG. 3 shows a typical initialisation message format 300. The first bytes are part of the header 200 described above. The remaining bytes comprise initialisation data 305.

The format for the remainder of the message is dependent on whether or not the message is used to carry updated token credit parameters.

FIG. 4 shows a typical power message format 400. The first bytes are part of the header 200.

Power data 405 contained in a power message is specific to the rate type.

The CPE in one configuration operates in post payment mode. Post payment mode is an arrangement between the utility supplier 110 and the customer in that the utility is supplied to the customer premises 105 and payment is made by the customer following supply of the utility. The CPE in another form is configured to operate in prepayment mode. In prepayment mode the utility meter is credited with a certain amount of credit. A utility is only supplied to a customer premises 105 subject to credit or sufficient credit stored in the utility meter 125.

A CPE is configured as either post payment or prepayment by the data contained in the power data 405. In post payment mode zero value rates are passed in the rate table which means that no money deductions occur inside the CPE. For this reason power is never switched off due to insufficient credit. In prepayment mode, non zero rates are passed in the rate table.

Power data 405 contains purchase amount for prepay, rate tables defining how or when money is deducted, debt remaining/loyalty point/EECA rating values that are viewable on the customer display, main switch override commands, customer specific parameters such as credit limit and so on.

As described above, the disconnect switch 120 can be operated in one of four modes. Power message format 400 optionally includes a new mode field 410. This field signals a new operating mode. In one embodiment the field has a default value indicating no change in mode. The field may have further possible values corresponding to the modes of automatic, forced on, forced off and armed respectively.

Date/time field 415 indicates a preferred date or time when the new operating mode is to take effect. Flag field 420 represents an acknowledgement/alert flag. This flag specifies which switching events will cause the meter to generate an alert message.

A typical global adjustment message format 500 is shown in FIG. 5. The message 500 contains a header 200.

Global adjustment messages in adjustment data 505 contain after hour hold off configuration information, time adjustment commands, main switch or auxiliary switch override commands, rate/auxiliary load time driven switching tables and so on.

A global adjustment message can be sent to a CPE group or to an individual CPE.

Global adjustment message format 500 optionally includes new mode field 510, date/time field 515 and flag field 520. Fields 510, 515 and 520 operate in the same way as fields 410, 415 and 420 respectively.

Messages are also generated by CPE 115 and transmitted to back office server 150. These messages include version messages, metering data messages, event information messages and diagnostic information messages.

Version messages contain version and configuration information including the version of hardware of the equipment forming the CPE 115, manufacturing information and general configuration information.

Metering data messages contain metering and other operational data.

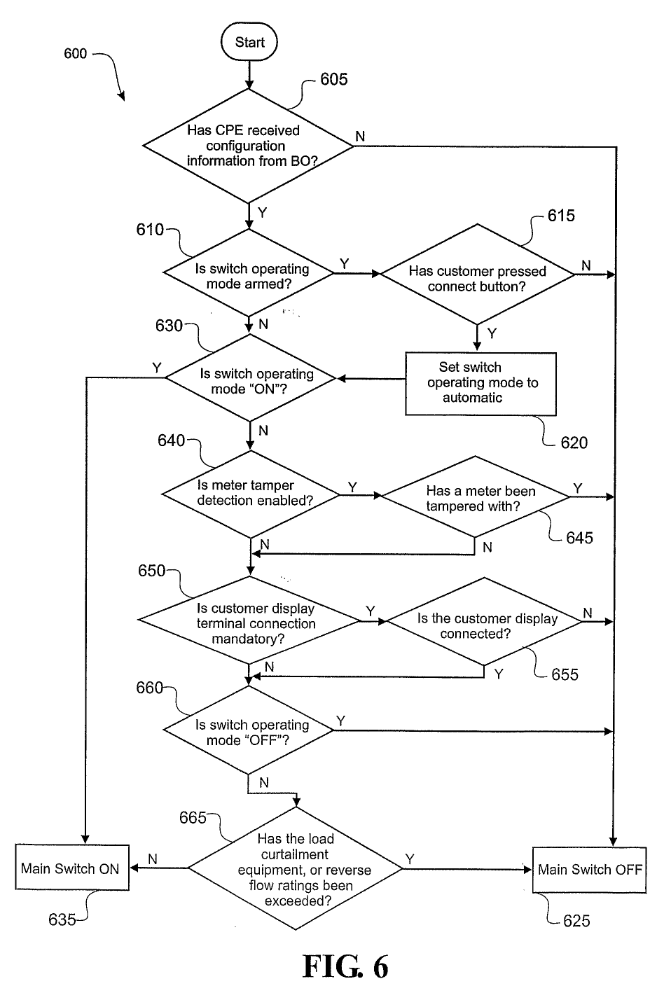

FIG. 6 shows a preferred form flowchart of operation 600 of the system 100 in which CPE 115 is configured to operate in post payment mode.

As shown in FIG. 6, the CPE first checks to ensure that configuration information has been received from the back office server. If the utility meter in the CPE has not received 605 configuration information from the management system, the disconnect switch is activated to terminate supply of the utility.

The switch is checked 610 to determine if the switch is operating in an “armed” mode. In an armed mode the system is designed to support a supervised reconnection of the supply. Supply is reconnected once acknowledgment is received that it is safe to do so. This acknowledgement can be invoked by the customer pressing a button that is available on the meter or customer display.

If 615 the customer presses the appropriate button during armed mode, the switch operating mode is set to automatic 620. Automatic mode is the normal operating mode for the switch. Supply is normally connected unless exception conditions exist. Examples of exception conditions include meter tampering and meters being in an unconfigured state.

If the CPE has not received configuration information then the disconnect switch is activated to terminate supply of the utility resulting in termination 625. If the switch is operating in an armed mode and the customer has not pressed the connect button then supply of the utility is also terminated 625.

The system then checks 630 to see whether the switch is operating in a forced on mode. In a forced on mode the supply is unconditionally connected. This mode is activated by the management system sending “override switch on command” to the utility meter.

Back office server 150 is configured to transmit an override switch command to CPE 115. An override switch ON command initiates or continues supply of the utility and an override switch OFF command terminates supply of the utility. An override switch command can be carried in either a power message or a global adjustment message. The commands can be configured to be executed immediately upon receipt of the message, or deferred until a specific date or time. The override switch command is also referred to as a latch switch operation that can be set to ON, set to OFF, or unlatched. In an unlatched state the CPE uses normal business rules described below to decide the switch state.

The disconnect switch is activated to initiate supply of the utility if 630 the utility meter has received an override switch ON command from back office server. If the command has been received, supply of the utility is initiated 635.

Meter tampering is preferably checked for and dealt with. If meter tampering 640 is enabled and a meter has been tampered with 645 then the disconnect switch is activated to terminate supply of the utility resulting in termination 625.

In one embodiment the detection of tampering with a meter results in a penalty or punishment delivered to the customer. In one embodiment, on detecting meter tampering, the disconnect switch is activated to terminate supply of the utility. In a further embodiment, utility supply is terminated for a predetermined penalty time period following termination of the supply of the utility. Possible options include disconnection for one minute, disconnection for thirty minutes and disconnection permanently.

A penalty rating in one form is assigned to the user on detecting tampering with the meter. The predetermined penalty time period is then calculated at least partly from the penalty rating. For example the first time that meter tampering is detected, one option is not to terminate supply of the utility, but assign a penalty rating such as “one tamper” to the customer.

Detection of tampering by a customer already assigned a “one tamper” rating would result in disconnection for one minute and a new rating assigned of “two tamper”. Detection of tampering by a customer with a “two tamper” rating would result in disconnection for thirty minutes and a new assigned rating of “three tamper”. Detection of tampering by a customer with a “three tamper” rating would result in permanent disconnection and the assigning of a “four tamper” to the customer.

A further preferred form embodiment enables detection of tampering with the customer display unit 130. If a customer display terminal connection is mandatory 650 and the customer display is not connected 655 then utility supply is terminated 625.

The detection of tampering with the customer display in one embodiment leads to termination of supply for a penalty time period similar to that described above with reference to meter tampering.

If the CPE receives an override switch OFF command 660 then switch is turned off 625 otherwise switch remains ON 635. An override switch off command is effective to cause the switch to operate in a forced off mode. In a forced off mode the supply is unconditionally disconnected.

In a further embodiment it is possible to disconnect supply for additional reasons when the disconnect switch is in an automatic operating mode. One reason is load curtailment. In load curtailment the demand of the customer on the supply exceeds specified limits. This is similar to the load limiting feature available in prepayment mode.

A further reason to disconnect supply is equipment ratings. This is where the customer's demand on the supply exceeds the ratings of installed equipment.

The system also checks for reverse flow. Reverse flow of supply, if it exceeds allowable limits for the installation, causes disconnection. As shown in FIG. 6 the system checks 665 for load curtailment, equipment ratings and reverse flow.

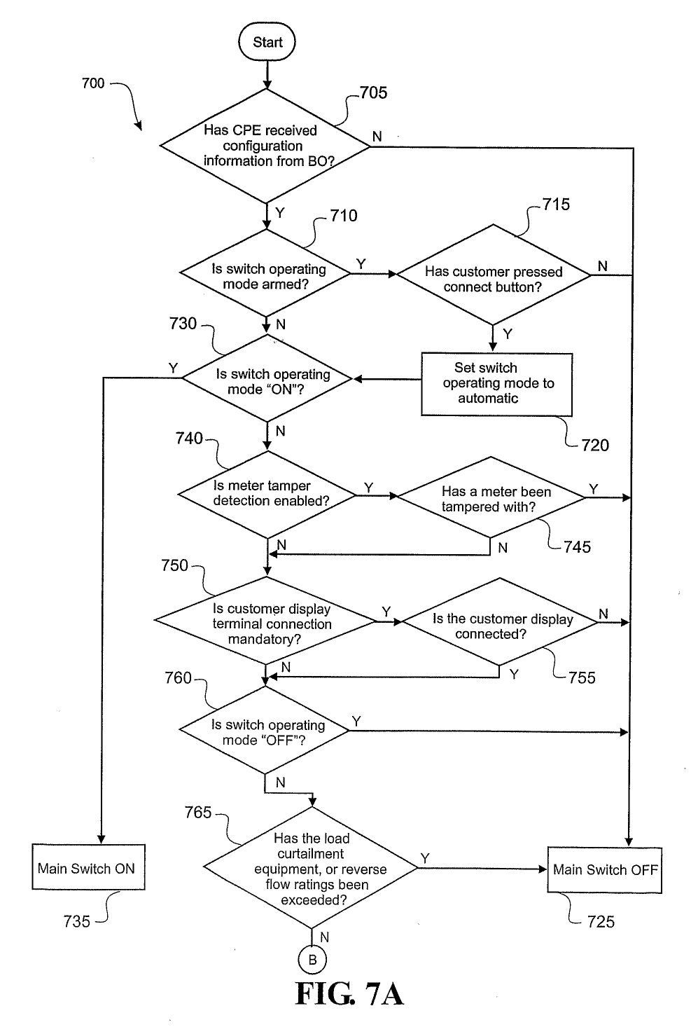

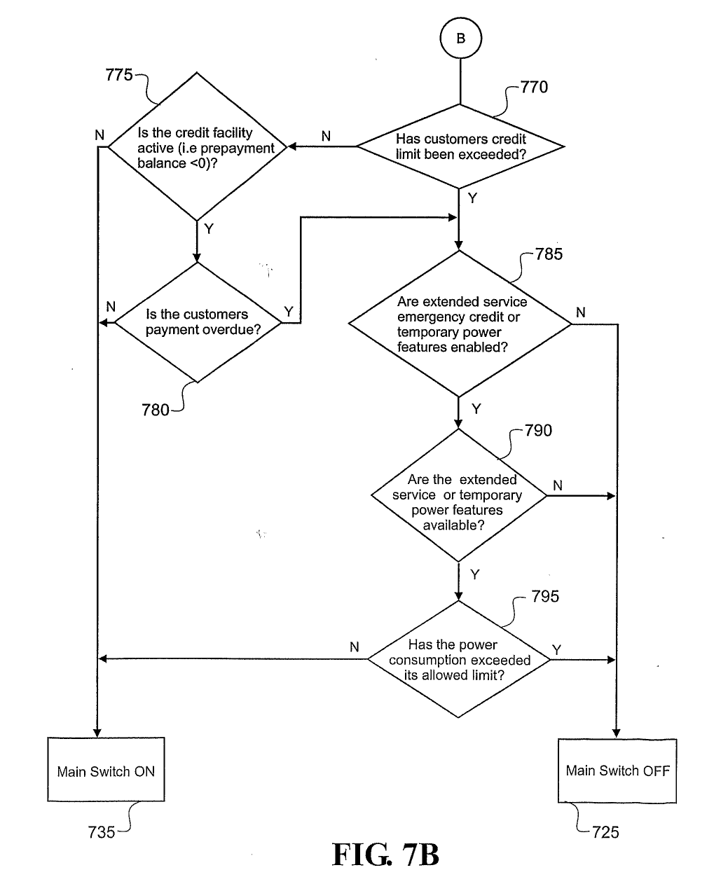

Referring to FIGS. 7A and 7B, the method 700 in one embodiment is also applied to a prepayment mode in which a utility meter is credited with a certain amount of credit.

Steps 705-765 proceed as described above with reference to FIG. 6 for steps 605-665.

As indicated at step 770, the CPE 115 checks to see whether a customer's credit limit has been exceeded. If the credit limit has not been exceeded, then the method checks 775 whether a credit facility is active. A customer can be assigned an optional credit limit. The credit limit permits a prepayment balance in the meter to go below zero. A credit limit of $0 means that the balance cannot go below $0. A credit limit of $10 means that the balance can drop to −$10.

If the credit facility is not active then utility supply continues 735.

If the customer has a credit limit greater than zero, the method checks 780 whether the customer payment is overdue. If the prepayment balance has gone below $0 then the credit facility is active. The CPE is configured to allow the credit facility to be available only for a predetermined number of consecutive days (for example 30). The customer is then obliged to make a payment that takes the prepayment balance above $0 at least once every 30 days.

The credit limit is assigned to the utility meter and a customer price is calculated at least partly on the utility supplied for the customer premises. The customer price is also preferably calculated using tariff or rate information as well as the amount of utility supplied. If the credit limit is greater than the customer price then the customer's credit limit has not been exceeded.

In some embodiments an extended service facility is provided to the customer. An extended service facility provides for example a customer to be supplied with electricity until the next working day by which the customer can purchase further credit to ensure continued supply.

If an extended service, emergency credit, or temporary power feature is not enabled 785—and the credit limit has been exceeded 770, then utility supply is terminated 725.

If the extended service or temporary power features are enabled 785 these features are then checked to see whether they are available 790. If they are not available then electricity is terminated 725.

In one preferred embodiment the extended service facility has associated with it an extended service limit. During the time the extended service facility is operational, the amount of utility provided to customer premises during the extended service facility operation is monitored. If utility consumption exceeds 795 the extended service limit during the extended service facility utility supply is terminated 725 otherwise utility supply continues 735.

When in extended service facility operation, average utility consumption could be monitored for a predetermined extended time period. A typical predetermined extended time period is fifteen minutes. If the average utility consumption exceeds the extended service limit during extended service facility operation, then the disconnect switch is activated to terminate supply of the utility. This termination could be effective for a predetermined time period following which supply is reinitiated.

In one example, if the average utility consumption exceeds the extended service limit, the utility is disconnected for fifteen minutes. Utility consumption is then measured over the next fifteen minutes and disconnection effective for a further fifteen minutes if the utility consumption is exceeded. This cycle repeats during extended service facility operation.

Where in the foregoing description reference has been made to elements or integers having known equivalents, then such equivalents are included as if they were individually set forth.

Although the invention has been described by way of example and with reference to particular embodiments, it is to be understood that modifications and/or improvements may be made without departing from the scope or spirit of the invention, as defined by the accompanying claims.

1. A method of managing supply of a utility to a customer premises in which a utility meter and a disconnect switch are installed at the customer premises and in which a management system remote from the customer premises is interfaced to the utility meter and disconnect switch over a data network, the method comprising:
transmitting a termination instruction over the data network causing activation of the disconnect switch to terminate supply of the utility if the utility meter has not received configuration information from the management system;
transmitting an initiation instruction over the data network, causing activation of the disconnected switch to initiate supply of the utility if the utility meter has received an override switch ON command from the management system;
transmitting a termination instruction over the data network causing activation of the disconnected switch to terminate supply of the utility on detecting tampering with the meter; and
transmitting a termination instruction over the data network causing activation of the disconnect switch to terminate supply of the utility if the utility meter has received an override switch OFF command from the management system.

2. The method as claimed in claim 1 further comprising transmitting a termination instruction over the data network causing activation of the disconnect switch to terminate supply of the utility on detecting tampering with a customer display terminal.

3. The claim of claim 1 further comprising transmitting an initiation instruction over the data network causing activation of the disconnect switch to initiate supply of the utility after a predetermined penalty time period following termination of the supply of the utility.

4. The method of claim 3 wherein the predetermined penalty time period is one minute.

5. The method of claim 3 wherein the predetermined penalty time period is 30 minutes.

6. The method of claim 3 further comprising:
assigning a penalty rating to the user on detecting tampering with the meter; and
calculating the predetermined penalty time period at least partly from the penalty rating.

7. The method of claim 1 further comprising:
assigning a credit limit to the utility meter; and
calculating a customer price based at least partly on utility supplied to the customer premises.

8. The method of claim 7 further comprising transmitting an initiation instruction over the data network causing activation of the disconnect switch to initiate supply of the utility if the credit limit is greater than the customer price.

9. The method of claim 7 further comprising transmitting an initiation instruction over the data network causing activation of the disconnect switch to initiate supply of the utility if the credit limit is greater than the customer price and if the customer's payment for the utility is not overdue.

10. The method of claim 7 further comprising:
providing an extended service facility to the utility meter; and
transmitting an initiation instruction over the data network causing activation of the disconnect switch to initiate supply of the utility if the customer price is greater than the credit limit.

11. The method of claim 10 further comprising:
associating an extended service limit with the extended service facility; and
monitoring the amount of utility provided to the customer premises during the extended service facility.

12. The method of claim 11 further comprising transmitting an initiation instruction over the data network causing activation of the disconnect switch to initiate supply of the utility if the amount of utility provided is less than the extended service limit.

13. The method of claim 11 further comprising transmitting a termination instruction over the data network causing activation of the disconnect switch to terminate supply of the utility if the amount of utility provided is greater than the extended service limit.

14. The method of claim 13 wherein the amount of utility provided is monitored for a predetermined extended time period, the method further comprising transmitting a termination instruction over the data network causing activation of the disconnect switch to terminate supply of the utility if the amount of utility provided within the predetermined extended time period is greater than the extended service limit.

15. The method of claim 14 further comprising transmitting an initiation instruction over the data network causing activation of the disconnect switch to initiate supply of the utility after the predetermined extended time period following termination of the supply of the utility.

16. The method of claim 1 further comprising:
receiving a user request to initiate supply of the utility; and
transmitting an initiation instruction over the data network causing actuation of the disconnect switch to initiate supply of the utility.

17. The method of claim 16 further comprising checking the disconnect switch for a predetermined operating mode and activating supply on detection of the predetermined operating mode.

18. The method of claim 16 wherein the user request comprises a key or button press by the user.
